(19) United States
(12) Patent Application Publication
(10) Pub. No.: US 2026/0188614 A1
(43) Pub. Date: Jul. 2, 2026

(54) System and Method for Delivering Pulsed RF Power from Multiple Generators to Multiple Loads

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 19/006,249

(22) Filed: Dec. 31, 2024

(51) Int. Cl. H01J 37/32

(52) U.S. Cl. CPC H01J 37/32146

(57) ABSTRACT

Disclosed is a system and method for delivering pulsed RF power and optionally tailored waveform voltage from multiple generators to multiple loads in semiconductor manufacturing processes. A controller designs master pulse train schemes for each load, defining pulse attributes such as RF frequency, power level, and duration. The controller coordinates pulse generation by the generators and dynamically routes the pulses to designated loads via a Multi-Pole Multi-Throw (MPMT) switch based on the schemes, ensuring flexibility and precision.

### FIELD

The present invention relates to systems and methods for delivering radio frequency (RF) power and, optionally, tailored waveforms from multiple power generators to multiple loads, particularly for use in semiconductor manufacturing processes requiring flexible, precise, and scalable power delivery control.

### BACKGROUND

In semiconductor manufacturing, processes such as plasma etching and deposition increasingly demand flexible and precise power delivery from multiple generators to multiple loads. Each load may require varying RF frequencies, power levels, and duty cycles, introducing significant complexity in coordinating power delivery across interconnected systems.

Existing systems often rely on static configurations, with individual generators dedicated to specific loads. This rigid approach lacks the flexibility to adapt to evolving process requirements or dynamically reallocate power to accommodate diverse load-specific needs.

The integration of tailored waveforms, operating below the RF frequency range, adds another layer of complexity. While tailored waveforms are advantageous for refining plasma parameters, such as ion energy distribution, their coexistence with RF power underscores the limitations of conventional systems in managing multiple power types effectively.

These challenges in flexibility, scalability, and coordination reveal critical shortcomings in current power delivery systems, underscoring the need for innovative solutions.

### SUMMARY

The present invention provides a system and method for delivering RF power from multiple generators to multiple loads with enhanced precision, flexibility, and scalability. The system employs a Multi-Pole Multi-Throw switch to route RF power and tailored waveform in pulsed forms, generated by multiple generators to multiple loads.

Central to the invention is a pulse scheme design engine in a controller that designs pulse train schemes for each generator and load. The pulse scheme design engine defines the characteristics of each pulse, including parameters such as frequency, power level, duty cycle, duration, and the designated load. In some implementations, these characteristics are encoded in metadata, which accompanies each pulse throughout its generation and delivery.

The switch network, implemented as a Multi-Pole Multi-Throw (MPMT) switch, plays a critical role in directing pulses to the designated loads. The controller may utilize the metadata to guide the operation of the switch network, ensuring that each pulse is delivered to its designated load with precision in timing. The system's ability to dynamically route pulses to multiple loads enables flexible power allocation and process customization for a variety of semiconductor manufacturing operations.

In one implementation, the system includes multiple generators capable of producing configurable pulse trains for the RF power or the tailored waveform. The pulse trains for each generator can be dynamically adjusted by the pulse design engine based on process requirements. The metadata associated with each pulse includes its timing, RF frequency, power level, duty cycle, duration, and designated load. The present inventive concept implemented in various embodiments ensures seamless coordination between generators, the switch network, and the loads.

The loads may include electrostatic chucks (ESCs) within plasma chambers, with the master pulse trains tailored to optimize plasma characteristics such as density, ion directionality, and ion energy distribution. The system supports tailored waveforms and mixed-frequency RF power, allowing precise control of plasma conditions to enhance process outcomes.

The invention offers a scalable and flexible solution for RF power and tailored waveform delivery, leveraging the pulse scheme design engine, metadata-based coordination, and a MPMT to enable efficient and precise power delivery across multiple loads. This approach enhances plasma process control, enabling consistent and optimized performance for semiconductor manufacturing applications.

### BRIEF DESCRIPTION OF DRAWINGS

For enhanced clarity, the following description refers to the accompanying drawings:

FIG. 1A: Depicts an exemplary RF system delivering RF power and tailored waveform from three generators to two loads using independent matches and a MPMT switch.

FIG. 1B: Depicts an exemplary RF system delivering RF power and tailored waveform from three generators to two ESCs to establish bias voltages and optimize plasma parameters.

FIG. 2: Illustrates a flowchart of the exemplary RF system's operation, highlighting the role of the pulse scheme design engine, metadata, and MPMT switch for precise delivery to designated loads.

### DETAILED DESCRIPTION

To ensure a comprehensive understanding of the present invention, this section explores detailed embodiments and technical aspects. Specific examples are provided for clarity; however, modifications and variations that align with the claims are considered within the scope of the invention. Conventional methods and components are discussed to emphasize the unique and inventive features of the system.

### Terms and Definitions

RF Power Generator: A device that generates RF power at specific frequencies and power levels, often modulated into pulse trains. These generators are configured to deliver RF power to optimize plasma characteristics in semiconductor manufacturing processes.
Multi-Pole Multi-Throw (MPMT) Switch: A dynamic switch network that routes RF power from multiple inputs (generators) to multiple outputs (loads), often implemented with high-speed components like GaN HEMTs, it enables flexible and precise RF power delivery.
GaN High-Electron-Mobility Transistor (GaN HEMT): High-performance transistors made from Gallium Nitride, offering fast switching (nanoseconds to microseconds), low conduction losses, and the ability to handle high RF power levels. These are critical for efficient operation in MPMT switches.
Pulse Train: A series of RF or tailored waveform power pulses with defined attributes, such as RF frequency, duty cycle, power level, duration, and designated load. Pulse trains are generated to meet specific process requirements.
Master Pulse Train: A composite pulse train designed for each load, composed of synchronized pulses from multiple generators. The master pulse train is generated by the pulse scheme design engine and ensures non-overlapping pulses for efficient RF power or tailored waveform delivery.
Pulse Scheme Design Engine: A system component that generates and manages pulse trains for RF generators and tailored waveform generators. It defines the attributes of each pulse, including frequency, power level, duration, and designated load.
Metadata: Information associated with each pulse that defines its parameters, including timing, RF frequency, power level, duty cycle, duration, and the designated load.
Controller: The central component that manages the operation of the RF system. It oversees the pulse scheme design engine, communicates pulse parameters to generators, and controls the MPMT switch to route pulses to the designated loads.
Matching Network (Match): A circuit used to align the impedance between an RF generator and its load, optimizing power transfer and reducing signal reflections.
Electrostatic Chuck (ESC): A powered electrode within a plasma chamber that holds substrates securely in place and delivers RF power to influence plasma parameters for processing.
Plasma Chamber: A chamber where plasma is generated and sustained for semiconductor processes, such as etching, deposition, or surface treatments. The plasma characteristics are controlled through RF power and tailored waveforms.
Capacitively Coupled Plasma (CCP) Reactor: A plasma reactor design featuring a powered electrode (e.g., ESC) and a grounded electrode (e.g., showerhead), where RF power is applied to create and sustain plasma.
Tailored Waveform: A custom-designed voltage waveform used to refine plasma characteristics, such as ion energy distribution, and substrate surface charge control, improving substrate processing outcomes.
Plasma Parameters: Characteristics of plasma, including density, ion energy distribution, and ion directionality. These parameters are controlled dynamically using pulse trains for RF power and tailored waveforms.

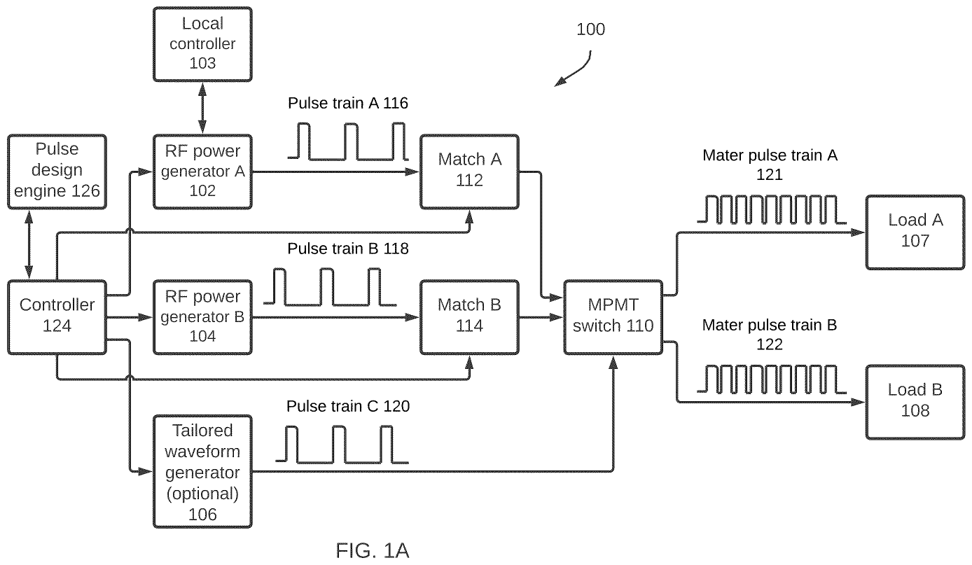

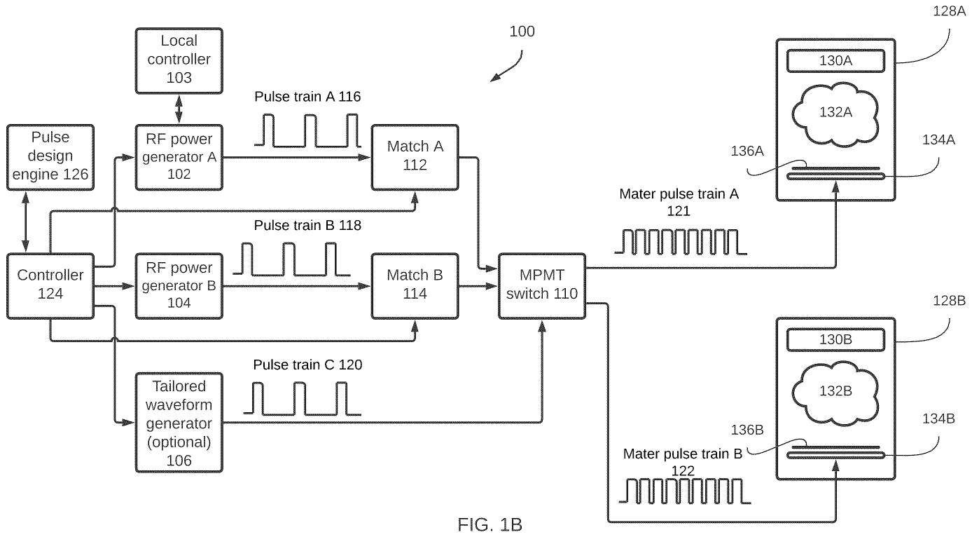

FIG. 1A illustrates an exemplary RF system (100) designed to deliver RF power and tailored waveforms from multiple generators (102, 104, 106) to two loads (107, 108). While the system is depicted with three generators and two loads for illustrative purposes, it is scalable to support varying numbers of generators and loads based on application requirements.

In some implementations, the generators may include RF power generators capable of outputting RF power at specific frequencies, such as 400 kHz, 1 MHz, or 13.56 MHz, with an output power range of 50 to 2000 watts. The system may also include a tailored waveform generator (106) that produces customized waveforms to optimize ion energy distribution. The output voltage for tailored waveform may be ranged from 100 to 10,000 volts. These waveforms may feature a constant positive voltage phase to neutralize positive ions trapped on the substrate surface from the prior pulse, mitigating residual surface charging effects and ensuring uniform electrical potential. This phase is followed by a negative voltage ramping phase, designed to maintain a constant surface potential by balancing positive ion accumulation. The ramping slope is optimized to conserve charge and enhance process stability, particularly beneficial for etching high-aspect-ratio structures or deposition operations requiring precise surface control.

The configuration in FIG. 1A includes two RF power generators (102, 104) and one tailored waveform generator (106), connected to the loads (107, 108) through a MPMT switch (110).

In one implementation, each RF power generator connects to the loads via a dedicated matching network, such as match A (112) for generator 102 and match B (114) for generator 104. The tailored waveform generator (106) may not require a matching network due to its lower operating frequency. Each generator's connection to the loads can be dynamically re-routed, with the matching networks incorporating electrically tunable components to accommodate varying load requirements.

The RF power and tailored waveforms from the generators (102, 104, 106) are delivered in the form of pulse trains (116, 118, 120), generated through square wave modulation with duty cycles ranging from 5% to 95% and frequencies between 100 Hz and 100 kHz.

The MPMT switch (110) is a critical component of the RF system (100). In some implementations, it utilizes GaN HEMTs for rapid switching, leveraging their high electron mobility, wide bandgap, and excellent thermal conductivity. These attributes enable efficient operation at high switching frequencies (up to several hundred megahertz) while managing significant power levels, making them ideal for semiconductor manufacturing applications requiring precise power control.

The switch's fast operation, with switching times from nanoseconds to microseconds, ensures accurate timing and power distribution under demanding plasma processing conditions. GaN HEMTs'low conduction losses and high breakdown voltage enhance reliability in high-power RF systems. Alternatively, the MPMT switch (110) may use technologies such as Si MOSFETs, SiC MOSFETs, or mechanical relays based on application needs. Independent switches may be employed to minimize impedance effects from unconnected paths, improving RF power delivery precision.

A controller (124) coordinates the system's operation, generating schemes of the master pulse trains A (121) and B (122) for loads A (107) and B (108), respectively. The controller (124) designs pulse trains (116, 118, 120) for each generator through a pulse design engine (126), implemented in software, firmware, hardware, or combinations thereof.

In some configurations, each generator includes a local controller, such as local controller (103) for RF power generator (102). The controller (124) communicates pulse train schemes, including parameters like frequency, power level, duty cycle, and duration, to the local controllers. Rules are implemented to prevent overlapping pulses within any pulse train, including the master pulse trains (121, 122).

The controller (124) and local controllers manage pulse timing across all pulse trains. In one implementation, each pulse is labeled with metadata specifying timing, RF frequency, power level, duty cycle, duration, and designated load. In some implementations, the controller (124) uses this metadata to direct pulses to designated loads via the MPMT switch (110) at precise times. Synchronization to a common clock ensures precise timing across generators, the switch, and matching networks.

A notable feature of the invention is the flexibility to combine RF signals and tailored waveform signals within pulse trains. This flexibility enables precise optimization of plasma parameters, such as density, ion energy distribution, and ion angular distribution, to achieve enhanced substrate processing performance.

FIG. 1B illustrates an implementation where the loads (107, 108) are ESCs (134A, 134B) located within plasma chambers (128A, 128B). The ESCs are used to securely hold substrates (136A, 136B) during processing. In one configuration, the plasma chambers (128A, 128B) employ the ESCs (134A, 134B) as powered electrodes, with showerheads (130A, 130B) functioning as grounded electrodes, forming capacitively coupled plasma (CCP) reactors. Plasmas (132A, 132B) are ignited by applying RF power to the ESCs, facilitating substrate (136A, 136B) processing.

In certain applications, the ESCs (134A, 134B) are supplied with mixed-frequency RF power. The higher-frequency component enhances plasma density, while the lower-frequency component increases ion energy and directionality. In other configurations, tailored waveforms are combined with RF power to achieve tighter ion energy distribution. The master pulse trains (121, 122), incorporating pulses with distinct RF frequencies, effectively optimize plasma density, ion energy, and directionality. Additionally, integrating tailored waveforms into the master pulse trains (121, 122) further refines ion energy distribution, improving overall process outcomes.

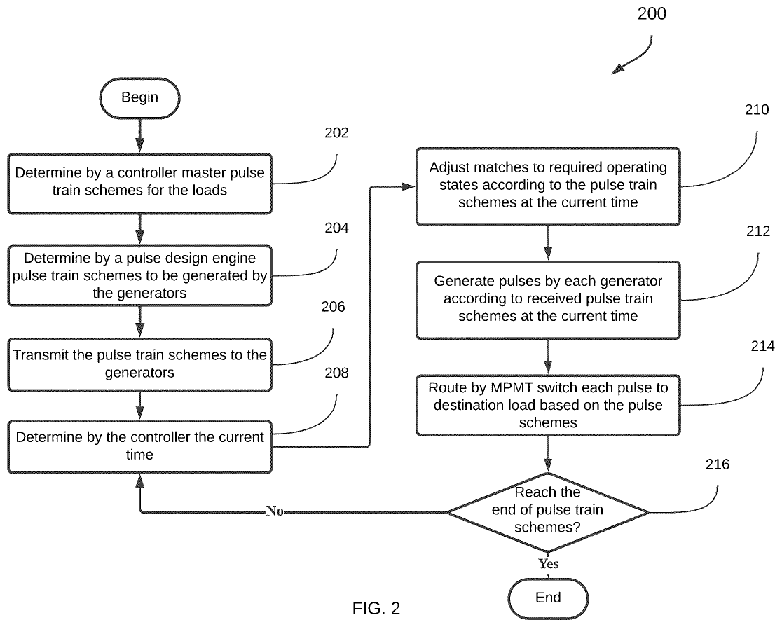

FIG. 2 presents a flowchart outlining a method (200) for delivering RF power from multiple generators to multiple loads. The process begins with step 202, where the controller (124) determines the master pulse train schemes for each load to meet output specifications following substrate processing. The scheme defines the timing, frequency, and power levels of the pulses constituting the master pulse trains (121, 122).

In step 204, the controller (124), using the pulse design engine (126), selects subsets of pulses within the master pulse trains (121, 122) to form pulse trains (116, 118, 120) for each generator (102, 104, 106), respectively. In some implementations, each pulse is associated with representative metadata.

In step 206, the schemes for the pulse trains (116, 118, 120) are transmitted to the local controllers of the generators like 103. In step 208, the controller (124) determines the current time using the common clock or calibrated clocks distributed within various components.

In step 210, the matches (112, 114) are adjusted to the required operating states based on the pulse train schemes or more specifically the associated metadata for the pulse parameters at the current time. The matches may be tuned to resonating states for specific pulse generation and switching operations. Tuning can involve adjusting electrically variable components within the matches or modifying operating frequencies.

In step 212, the generators produce the designated pulses according to the pulse train schemes or the metadata. In step 214, the generated pulses are routed to their respective designated loads via the MPMT switch (110).

In step 216, the controller (124) checks whether all pulses have been delivered. If all pulses have been processed, the process (200) is completed. Otherwise, the controller (124) repeats steps 208 to 216 until all pulses are delivered to the designated loads.

1. An RF system for a semiconductor manufacturing process system, comprising:
a plurality of generators, each configured to generate RF power or tailored waveform voltage in the form of pulse trains;
a plurality of loads, each configured to receive RF power or tailored waveform voltage in the form of master pulse trains;
an MPMT switch configured to dynamically route pulses in the master pulse trains from the plurality of generators to the plurality of loads; and
a controller configured to design pulse schemes for the pulse trains and the master pulse trains and coordinate the operations of the generators and the MPMT switch.

2. The system of claim 1, wherein the controller includes a pulse scheme design engine configured to generate pulse schemes that define attributes comprising timing, RF frequency, power level, and designated load for each pulse.

3. The system of claim 2, wherein each pulse is represented by metadata encoding attributes selected from timing, RF frequency, power level, duty cycle, duration, and designated load.

4. The system of claim 1, wherein the MPMT switch routes pulses from the generators to the loads based on the metadata associated with each pulse.

5. The system of claim 4, wherein the MPMT switch is implemented using GaN high-electron-mobility transistors (GaN HEMTs) to enable high-speed and high-power switching.

6. The system of claim 1, wherein the plurality of loads includes ESCs within plasma chambers, each configured to receive RF power or tailored waveform voltage to control plasma characteristics.

7. The system of claim 6, wherein the plasma characteristics include ion energy distribution.

8. The system of claim 2, wherein the pulse design engine adjusts pulse schemes based on substrate processing requirements, generating non-overlapping pulse trains for the generators and the loads.

9. The system of claim 1, wherein the master pulse trains for each load comprise pulses with distinct RF frequencies, power levels, and durations tailored to optimize the load's performance.

10. The system of claim 1, wherein the controller ensures that the generators, the MPMT switch, and the loads operate in synchronization to implement the master pulse train schemes.

11. A method for delivering RF power in a semiconductor manufacturing process system, comprising:
a) providing an RF system comprising a plurality of RF power generators, a plurality of loads, an MPMT switch, matches, and a controller;
b) designing, by the controller, master pulse train schemes for each load, wherein the schemes define attributes of each pulse;
c) determining, by the controller, pulse trains for each generator based on the master pulse train schemes;
d) transmitting, by the controller, the pulse train schemes to the generators;
e) determining, by the controller, the current time;
f) adjusting matches into the operating state according to the pulse train schemes at the current time;
g) generating, by the RF power generators, pulses with defined parameters according to the pulse train schemes at the current time;
h) routing, by the MPMT switch, the generated pulses to the designated loads; and
i) repeating steps e) to h) until reaching the end of the pulse train schemes.

12. The method of claim 11, wherein the loads comprise ESCs holding substrates in plasma chambers.

13. The method of claim 12, wherein the master pulse train schemes are determined based on the output specifications of the substrates.

14. The method of claim 11, wherein each pulse is represented by metadata uniquely associated with each pulse, including attributes comprising at least one of the following: timing, RF frequency, power level, duty cycle, duration, and designated load.

15. The method of claim 14, wherein the MPMT switch routes pulses from the generators to the loads based on the metadata.

16. The method of claim 11, wherein the MPMT switch is implemented using GaN HEMTs for high-speed, high-power switching.

17. The method of claim 12, wherein the master pulse trains delivered to the ESCs are used to optimize plasma processing by controlling plasma parameters.

18. The method of claim 17, wherein the plasma parameters include plasma density, ion energy distribution, and ion directionality.

19. The method of claim 11, wherein the master pulse trains for each load comprise pulses with distinct RF frequencies, power levels, and durations tailored to the specific plasma processing requirements of the loads.

20. The method of claim 11, wherein the controller ensures synchronization between pulse generation, adjusting matches and routing by the MPMT switch.
